(19) United States
(12) Patent Application Publication
(10) Pub. No.: US 2016/0246084 A1
(43) Pub. Date: Aug. 25, 2016

(54) Method of Manufacturing Flexible Display Device and Flexible Display Device

(71) Applicant: BOE TECHNOLOGY GROUP CO., LTD., Beijing (CN)

(72) Inventors: Lu Liu, Beijing (CN); Ming Che Hsieh, Beijing (CN)

(21) Appl. No.: 14/769,163

(22) PCT Filed: Oct. 27, 2014
(86) PCT No.: PCT/CN2014/089576

§ 371 Date: Aug. 20, 2015

(30) Foreign Application Priority Data
Aug. 21, 2014 (CN) 201410415163.6

(51) Int. Cl. G02F 1/1333

(52) U.S. Cl. CPC G02F 1/1333; G02F 1/133305

(57) ABSTRACT

A method for manufacturing a flexible display device and the flexible display device are disclosed. The method includes: forming a sacrifice layer on a base substrate; forming a flexible substrate on the sacrifice layer; forming components of the flexible display device on the flexible substrate; irradiating the sacrifice layer with laser to separate the base substrate from the flexible substrate; and coating a material used to make a protection layer on the flexible display device by a melted extrusion method for multiple times and cooling the material to form the protection layer. As a melted-extruding and coating method is applied to form the protection layer, pressure on components inside the flexible display device is reduced. Therefore, potential damage on the components inside the flexible display device is reduced and creation of air bubbles between film layers is avoided.

### TECHNICAL FIELD

Embodiments of the present invention relate to a method of manufacturing a flexible display device and the flexible display device manufactured by the method.

### BACKGROUND

Liquid crystal display (LCD) technologies have developed dramatically in a recent decade, with great improvement from display sizes to display quality. Because a flexible display itself has a special bendable feature, the flexible display may be applied in many special user experiences. In existing technologies, an adhesion-peeling method is generally applied to manufacture flexible display devices.

### SUMMARY

According to embodiments of the present invention, a method for manufacturing flexible display devices is provided, comprising: forming a sacrifice layer on a base substrate; forming a flexible substrate on the sacrifice layer; forming components of the flexible display device on the flexible substrate; irradiating the sacrifice layer with laser to separate the base substrate from the flexible substrate; and coating a material used to make a protection layer on the flexible substrate by a melted extrusion method for multiple times and cooling the material to form the protection layer.

In an example, the material for the sacrifice layer is one of amorphous silicon (a-Si), silicon oxide, silicon nitride and indium tin oxide (ITO).

In an example, the step of irradiating the sacrifice layer with laser to separate the base substrate from the flexible substrate comprises: absorbing the components of the flexible display device and rotating the flexible display device by 180 degrees by using a vacuum absorption manipulator, and then irradiating the sacrifice layer with laser to separate the flexible substrate from the base substrate.

In an example, the base substrate is a glass substrate.

According to embodiments of the present invention, another method for manufacturing flexible display devices is also provided, comprising: forming a sacrifice layer on a base substrate; forming components of the flexible display device on the sacrifice layer; irradiating the sacrifice layer with laser to separate the base substrate from the components of the flexible display device; and coating a material used to make a protection layer on the flexible display device by a melted extrusion method for multiple times and cooling the material to form the protection layer.

In an example, the material for the sacrifice layer is one of a-Si, silicon oxide, silicon nitride and indium tin oxide (ITO).

In an example, the step of irradiating the sacrifice layer with laser to separate the base substrate from the components of the flexible display device comprising: absorbing the components of the flexible display device and rotating the flexible display device by 180 degrees by using a vacuum absorption manipulator, and then irradiating the sacrifice layer with laser to separate the components of the flexible display device from the base substrate.

In an example, the base substrate is a glass substrate.

According to embodiments of the present invention, a flexible display device is provided. The flexible display device is made using any one of the methods described above.

### BRIEF DESCRIPTION OF THE DRAWINGS

In order to clearly illustrate the technical solution of the embodiments of the invention, the drawings of the embodiments will be briefly described in the following; it is obvious that the described drawings are only related to some embodiments of the invention and thus are not limitative of the invention.

FIGS. 1a to 1d show schematic views of a display device structure corresponding to a manufacturing process of a flexible display device provided in embodiments of the present invention.

Labels in the drawings:

| | |
|---|---|
| 1-base substrate | 2-sacrifice layer |
| 3-components of the flexible display device | 4-vacuum absorption |
| | manipulator |
| 5-extrusion and coating apparatus | 6-protection layer |

### DETAILED DESCRIPTION

In order to make objects, technical details and advantages of the embodiments of the invention apparent, the technical solutions of the embodiments will be described in a clearly and fully understandable way in connection with the drawings related to the embodiments of the invention. Apparently, the described embodiments are just a part but not all of the embodiments of the invention. Based on the described embodiments herein, those skilled in the art can obtain other embodiment(s), without any inventive work, which should be within the scope of the invention.

A known adhesion-peeling method includes: forming a sacrifice layer on a glass substrate; disposing a flexible substrate on the sacrifice layer; then forming components of the flexible display device on the flexible substrate; afterwards, separating the flexible display device, the sacrifice layer and the glass substrate with laser; and finally pressing and coating a protection layer on the flexible substrate to form the flexible display device.

However, during the pressing and coating of the protection layer, a coating machine is usually used to press and coat the protection layer that is attached with back glues on the flexible display device. The pressing and coating process may easily damage the components inside the flexible display device and cause creation of air bubbles, which produces pressure on the flexible display device and results in damage on one or more particular components of the flexible display device. Therefore, quality of the entire flexible display device may be affected.

### Embodiment 1

According to embodiments of the present invention, a method for manufacturing flexible display devices is provided, comprising:
step S101: forming a sacrifice layer on a base substrate;
step S102: forming a flexible substrate on the sacrifice layer;
step S103: forming components of a flexible display device on the flexible substrate;
step S104: irradiating the sacrifice layer with laser to separate the base substrate from the flexible substrate; and
step S105: coating a material used to make a protection layer on the flexible substrate by a melted extrusion method for multiple times and cooling the material to form the protection layer.

In the method of manufacturing flexible display devices provided in embodiments of the present invention, a melted extruding and coating method is applied to form the protection layer. Compared to forming the protection layer using the known pressing and coating method, pressure on components inside the flexible display device is reduced. Therefore, potential damage on the components inside the flexible display device is reduced and creation of air bubbles between film layers is avoided. In addition, it is convenient to adjust a thickness of the protection layer by using the melted extruding and coating method.

Thus, the method of manufacturing flexible display devices provided in embodiments of the present invention can improve production efficiency of flexible display devices and quality of the flexible display devices.

In an example, a thickness of the protection layer is controlled by a number of coating layers. For example, the thickness of the protection layer is 10-150 micrometers.

In an example, various materials are used for the sacrifice layer, as long as the materials are easy to be removed. For example, the material for the sacrifice layer is one of a-Si (amorphous silicon), silicon oxide, silicon nitride and ITO.

In an example, the step S104 comprises: absorbing the components of the flexible display device and rotating the flexible display device by 180 degrees using a vacuum absorption manipulator; and irradiating the sacrifice layer with laser to separate the flexible substrate from the base substrate. After rotation of the flexible display device by 180 degrees, the components of the flexible display device are located at the bottom. When irradiating the sacrifice layer with laser, the sacrifice layer may be removed and the flexible substrate may be separated from the base substrate. In the step S105, the protection layer is coated on the flexible substrate.

In an example, various materials are used for the base substrate. For example, the base substrate is a glass substrate.

### Embodiment 2

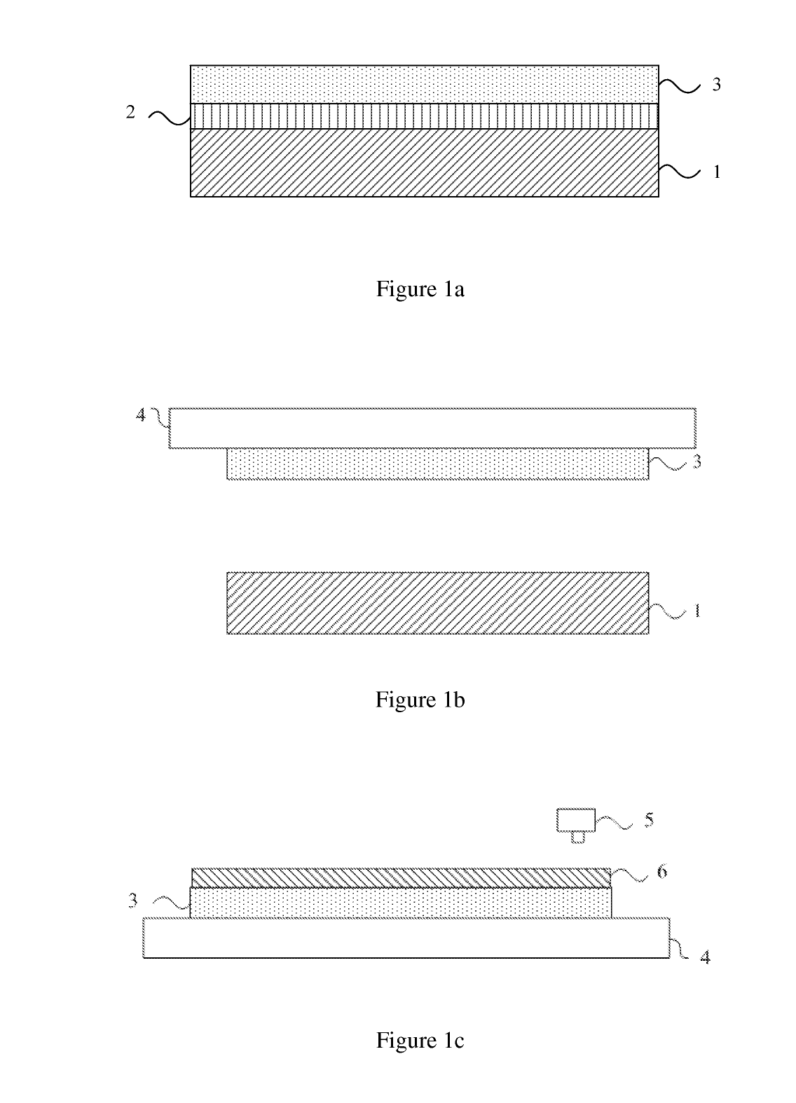

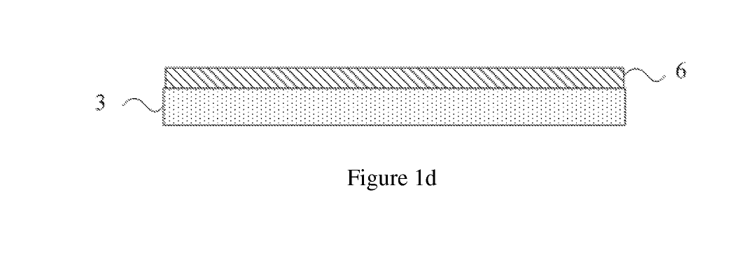

FIGS. 1a to 1d show schematic views of a display device structure corresponding to a manufacturing process of a flexible display device provided in embodiments of the present invention. Referring to FIGS. 1a to 1d, the method for manufacturing flexible display devices provided in embodiments of the present invention comprises:
step S201: forming a sacrifice layer 2 on a base substrate 1;
step S202: forming components 3 of a flexible display device on the sacrifice layer 2, as illustrated in FIG. 1a;
step S203: irradiating the sacrifice layer 2 with laser to separate the base substrate 1 from the components 3 of the flexible display device, as illustrated in FIG. 1b;

step S204: coating a material used to make a protection layer on the flexible display device by a melted extrusion method for multiple times and cooling the material to form the protection layer 6, as illustrated in FIG. 1c. For example, the material used to form the protection layer 6 is melted first, and then the melted material is coated on the flexible display device using an extruding and coating apparatus 5.

The flexible display device manufactured by performing the steps described above is illustrated in FIG. 1d.

Comparing Embodiment 2 to Embodiment 1, the step of forming the flexible substrate in Embodiment 1 is omitted, and the components 3 of the flexible display device are formed directly on the sacrifice layer 2. Thus, a total time for manufacturing the flexible display device is reduced because the additional time needed to cure the flexible substrate to become a film during the manufacture of the flexible substrate is omitted. Besides, the flexible substrate has a yellow color, which may be detrimental for the formation of the components of a bottom-emitting flexible display device.

In an example, a thickness of the protection layer is controlled by a number of coating layers. For example, the thickness of the protection layer is 10-150 micrometers.

In an example, various materials are used for the sacrifice layer, as long as the materials are easy to be removed. For example, the material for the sacrifice layer is one of a-Si, silicon oxide, silicon nitride and ITO.

In an example, the step S203 comprises: absorbing the components 3 of the flexible display device and rotating the flexible display device by 180 degrees using a vacuum absorption manipulator 4; and irradiating the sacrifice layer 2 with laser to separate the components 3 of the flexible display device from the base substrate 1. After rotation of the flexible display device by 180 degrees, the components 3 of the flexible display device are located at the bottom. When irradiating the sacrifice layer 2 with laser, the sacrifice layer 2 is removed and the components 3 of the flexible display device are separated from the base substrate 1. In the step S204, the protection layer is coated on a side of the components 3 that was attached to the sacrifice layer 2.

In an example, various materials are used for the base substrate 1. For example, the base substrate is a glass substrate.

### Embodiment 3

The embodiment of the present invention provides a flexible display device that is manufactured by using any one of methods described above with reference to Embodiment 1 and Embodiment 2. Because pressure on components inside a flexible display device can be reduced by using any one of the methods described above, potential damage on the components inside the flexible display device is reduced and creation of air bubbles between film layers is avoided. Thus, the flexible display device manufactured by any one of the methods described above have a better quality.

What is described above is related to the illustrative embodiments of the disclosure only and not limitative to the scope of the disclosure; the scopes of the disclosure are defined by the accompanying claims.

The present application claims the priority of Chinese patent application No. 201410415163.6 filed on Aug. 21, 2014, the disclosure of which is incorporated herein by reference in its entirety.

1. A method for manufacturing a flexible display device, comprising:
forming a sacrifice layer on a base substrate;
forming a flexible substrate on the sacrifice layer;
forming components of the flexible display device on the flexible substrate;
irradiating the sacrifice layer with laser to separate the base substrate from the flexible substrate; and
coating a material used to make a protection layer on the flexible substrate by a melted extrusion method for multiple times and cooling the material to form the protection layer.

2. The method as claimed in claim 1, wherein a material for the sacrifice layer is one of amorphous silicon, silicon oxide, silicon nitride and indium tin oxide.

3. The method as claimed in claim 2, wherein the material for the sacrifice layer is indium tin oxide.

4. The method as claimed in claim 1, wherein the step of irradiating the sacrifice layer with laser to separate the base substrate from the flexible substrate comprises:
absorbing the components of the flexible display device and rotating the flexible display device by 180 degrees by using a vacuum absorption manipulator; and
irradiating the sacrifice layer with laser to separate the flexible substrate from the base substrate.

5. The method as claimed in claim 1 wherein the base substrate is a glass substrate.

6. A method for manufacturing flexible display devices, comprising:
forming a sacrifice layer on a base substrate;
forming components of the flexible display device on the sacrifice layer;
irradiating the sacrifice layer with laser to separate the base substrate from the components of the flexible display device; and
coating a material used to make a protection layer on the flexible display device by a melted extrusion method for multiple times and cooling the material to form the protection layer.

7. The method as claimed in claim 6, wherein a material for the sacrifice layer is one of amorphous silicon, silicon oxide, silicon nitride and indium tin oxide.

8. The method as claimed in claim 7, wherein the material for the sacrifice layer is indium tin oxide.

9. The method as claimed in claim 6, wherein the step of irradiating the sacrifice layer with laser to separate the base substrate from the components of the flexible display device comprises:
absorbing the components of the flexible display device and rotating the flexible display device by 180 degrees by using a vacuum absorption manipulator; and
irradiating the sacrifice layer with laser to separate the components of the flexible display device from the base substrate.

10. The method as claimed in claim 6, wherein the base substrate is a glass substrate.

11. A flexible display device manufactured by the method according to claim 1.

12. A flexible display device manufactured by the method according to claim 6.
